(19) United States
(12) Patent Application Publication
(10) Pub. No.: US 2025/0062181 A1
(43) Pub. Date: Feb. 20, 2025

(54) Semiconductor Package With Thermal Conductive Structure and the Methods of Forming the Same

(71) Applicant: Taiwan Semiconductor Manufacturing Co., Ltd., Hsinchu (TW)

(72) Inventors: Chao-Wei Chiu, Hsinchu (TW); Hsuan-Ting Kuo, Taichung City (TW); Hsiu-Jen Lin, Zhubei City (TW); Ching-Hua Hsieh, Hsinchu (TW)

(21) Appl. No.: 18/507,726

(22) Filed: Nov. 13, 2023

Related U.S. Application Data
(60) Provisional application No. 63/532,442, filed on Aug. 14, 2023.

(51) Int. Cl. H01L 23/367; H01L 23/00; H01L 23/498; H01L 25/065

(52) U.S. Cl. CPC H01L 23/3675; H01L 23/49816; H01L 24/16; H01L 24/32; H01L 24/33; H01L 24/73; H01L 25/0652; H01L 2224/16225; H01L 2224/32225; H01L 2224/32245; H01L 2224/33519; H01L 2224/73204; H01L 2224/73253; H01L 2225/065; H01L 2924/1611; H01L 2924/16235

(57) ABSTRACT

A method includes depositing a first metal layer on a package component, wherein the package component comprises a first device die, forming a dielectric layer on the package component, and plating a metal thermal interface material on the first metal layer. The dielectric layer includes portions on opposing sides of the metal thermal interface material. A heat sink is bonded on the metal thermal interface material. The heat sink includes a second metal layer physically joined to the metal thermal interface material.

### PRIORITY CLAIM AND CROSS-REFERENCE

This application claims the benefit of the following provisionally filed U.S. Patent application: Application No. 63/532,442, filed on Aug. 14, 2023, and entitled “Semiconductor Package with Thermal Conductive Structure,” which application is hereby incorporated herein by reference.

### BACKGROUND

With the increasingly higher density and higher drive currents of integrated circuit devices, heat dissipation becomes a more severe requirement. Conventional solid TIMs have relatively low thermal conductivity, and cannot meet the high heat-dissipation requirement. Indium TIMs, on the other hand, has low melting point, which is also lower than the melting point of solder. This results in the indium TIMs to melt again in subsequent packaging process in which the solders are molten. The re-melting of the indium TIMs may cause void and low coverage.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1, 2A, 2B, 3-4, 5A, 5B, 6A, 6B, 7, 8A, and 8B illustrate the views of intermediate stages in the formation of a TIM-built-in package including a built-in metal thermal interface material (TIM) in accordance with some embodiments.

FIG. 9 illustrates a package including a TIM-built-in package in accordance with some embodiments.

FIGS. 10-13 illustrate the views of intermediate stages in the formation of a package including a TIM-built-in package and a sunroof metal lid in accordance with some embodiments.

FIGS. 14-16 illustrate the views of intermediate stages in the formation of a package including a TIM-built-in package and a metal lid in accordance with some embodiments.

FIG. 17 illustrates a package including a TIM-built-in package and a metal lid in accordance with some embodiments.

FIGS. 18-22 illustrate the views of intermediate stages in the formation of a TIM-built-in package in accordance with alternative embodiments.

FIG. 23 illustrates a process flow for forming a package in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “underlying,” “below,” “lower,” “overlying,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

A package including a built-in thermal interface material (TIM) and the method of forming the same are provided. In accordance with some embodiments, a first metal TIM is plated on a package that includes device dies. The first metal TIM may be plated, and may include copper. A dielectric layer (which may be a polymer region) may be formed on opposing sides of the first metal TIM. A metal lid including a second metal TIM may be bonded to the first metal TIM. With the metal TIMs being formed of metals such as copper, better thermal conductivity is achieved. Also, the metal TIMs have high melting points, so that they do not melt in the subsequent reflow processes for reflowing solder regions.

Embodiments discussed herein are to provide examples to enable making or using the subject matter of this disclosure, and a person having ordinary skill in the art will readily understand modifications that can be made while remaining within contemplated scopes of different embodiments. Throughout the various views and illustrative embodiments, like reference numbers are used to designate like elements. Although method embodiments may be discussed as being performed in a particular order, other method embodiments may be performed in any logical order.

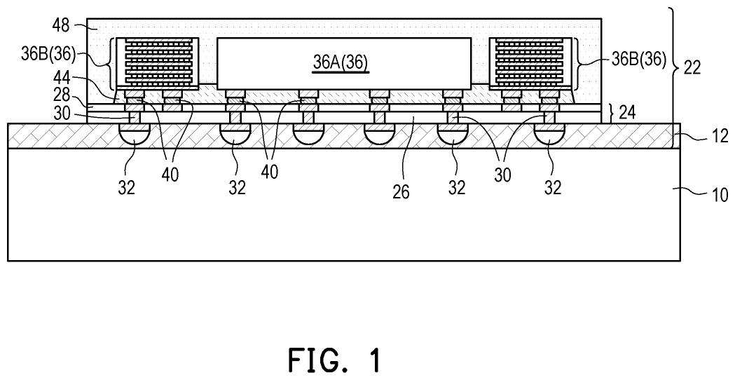

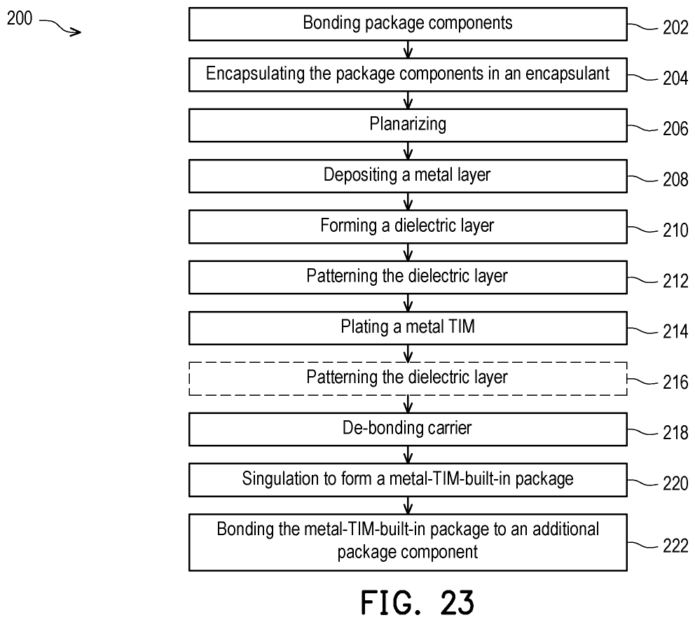

FIGS. 1, 2A, 2B, 3-4, 5A, 5B, 6A, 6B, 7, 8A, and 8B illustrate the views of intermediate stages in the formation of a TIM-built-in package including a built-in metal TIM in accordance with some embodiments. The corresponding processes are also reflected schematically in the process flow shown in FIG. 23.

Referring to FIG. 1, carrier 10 is provided. In accordance with some embodiments, carrier 10 is a glass carrier, an organic carrier, or the like. Release film 12 is formed on carrier 10 for attaching package components to carrier 10. Release film 12 may be formed of a Light-To-Heat-Conversion (LTHC) material, which is capable of being decomposed when exposed to a light beam such as a laser beam.

Further referring to FIG. 1, package component 22 is formed. Package component 22 may be a reconstructed wafer in accordance with some embodiments, with a device wafer therein, and device dies, interposers, die stacks, packages, and the like bonded to the device wafer. In accordance with some embodiments, package component 22 includes package components 24, 36A, and 36B.

In accordance with some embodiments, package component 24 is an interposer wafer including interposers therein, which include substrate 26 and the corresponding dielectric layers 28. Accordingly, package component 24 may be referred to as interposer wafer 24, while package component 24 may also be of other types. The structure of interposer wafer 24 is illustrated schematically, and the details such as the plurality of dielectric layers on the top side and bottom side of substrate 26, metal lines and vias, metal pads, and/or the like, are not shown.

Through-substrate vias 30 (sometimes referred to as through-silicon vias 30 when the substrate 26 is a silicon substrate) penetrate through substrate 26. Through-substrate vias 30 are used to interconnect the conductive features on the top side to the conductive features on the bottom side of substrate 26. Electrical connectors 32, which may include solder regions, may be underlying and joined to interposers, and are used to bond interposer wafer 24 to package component 22.

In accordance with some embodiments, package components 36A and 36B are bonded to the respective underlying interposer wafer 24. FIG. 1 illustrates a cross-section in which one package component 36A and two package components 36B are visible, and are bonded to the same interposer wafer 24. Package components 36A and 36B are different types of package components, and are collectively referred to as package components 36.

Each of package components 36 may be a device die, a package with a device die(s) packaged therein, a System-on-Chip (SoC) die including a plurality of integrated circuits (or device dies) integrated as a system, or the like. The device dies in package components 36 may be or may comprise logic dies, memory dies, input-output dies, Integrated Passive Devices (IPDs), or the like, or combinations thereof. For example, the logic device dies in package components 36 may be Central Processing Unit (CPU) dies, Graphic Processing Unit (GPU) dies, mobile application dies, Micro Control Unit (MCU) dies, BaseBand (BB) dies, Application processor (AP) dies, or the like. The memory dies in package components 36 may include Static Random-Access Memory (SRAM) dies, Dynamic Random-Access Memory (DRAM) dies, or the like. The device dies in package components 36 may include semiconductor substrates and interconnect structures.

In the subsequent discussion in accordance with some example embodiments, package components 36A are referred to as device dies, which may be SoC dies in accordance with some embodiments. Package components 36B may be memory stacks such as High-Performance Memory (HBM) stacks. Package components 36B may include memory dies forming a die stack, and an encapsulant (such as a molding compound) encapsulating the memory dies therein. In accordance with some embodiments, package components 36A are capable of generating more heat during operation, and thus are hotter than package components 36B.

Further referring to FIG. 1, package components 36 may be bonded to the underlying interposer wafer 24, for example, through solder regions 40. Underfill 44 is dispensed between package components 36 and the underlying interposer wafer 24. In accordance with some embodiments, package component 22 is formed through a Chip-on-Wafer (CoW) bonding process, wherein package components 36, which are discrete chips/packages, are bonded to the package components (such as dies) that are in an unsawed wafer 24 to form a reconstructed wafer. After the dispensing of underfills 44, an encapsulant such as molding compound 48 may be applied to encapsulate package components 36.

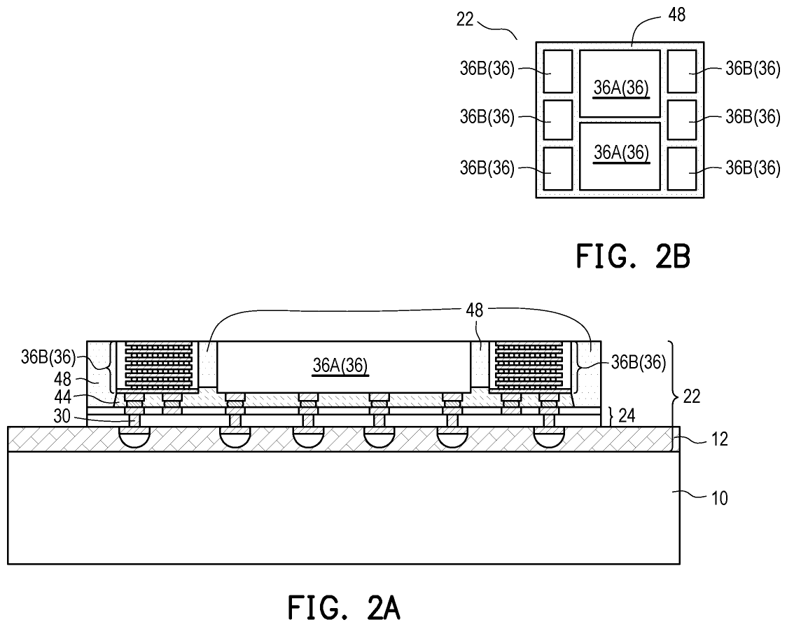

Next, referring to FIG. 2A, which illustrates a cross-sectional view, a planarization process such as a Chemical Mechanical Polish (CMP) process or a mechanical grinding process is performed to level a top surface of the molding compound 48 to the top surfaces of package components 36. A package component 22 is thus formed, which is alternatively referred to as a reconstructed wafer.

FIG. 2B illustrates an example top view of some features as shown in FIG. 2A. Package component 22 may include one or more device die(s) 36A, and a plurality of memory stacks 36B. Each of memory stacks 36B may include stacked memory dies and a molding compound molding (and encircling) the memory dies. Encapsulant (for example, a molding compound) 48 fills the spaces between neighboring package components 36.

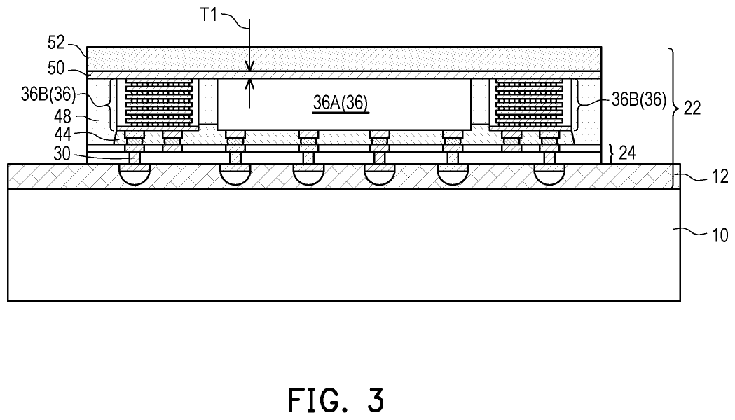

Referring to FIG. 3, metal layer 50 is formed through a deposition process. In accordance with some embodiments, metal layer 50 may be formed through Physical Vapor Deposition (PVD). Metal layer 50 may include a single metal layer, or may be a composite layer including multiple metal layers formed of or comprising different metals. The single metal layer or each of the multiple metal layers may be formed of a homogenous metallic material, a metal alloy, or the like. In accordance with some embodiments, the metal layer(s) in metal layer 50 may comprises a titanium layer, a copper layer, an aluminum layer, or the like, alloys thereof, and/or multi-layers thereof. For example, metal layer 50 may include a metal seed layer, which may include a titanium layer and a copper layer over the titanium layer. Alternatively, metal layer 50 may be a copper layer. In accordance with some embodiments, the thickness T1 of metal layer 50 may be in the range between about 0.01 μm and about 0.1 μm.

Metal layer 50 may be in contact with the silicon substrates of the device dies in package components 36A and 36B. Since metal layer 50 has a higher thermal conductivity than the silicon substrates of the device dies in in package components 36A and 36B, forming metal layer 50 to contact the silicon substrates of package components 36 may help to dissipate the heat generated by package components 36A and 36B.

Dielectric layer 52 is formed over metal layer 50. In accordance with some embodiments, dielectric layer 52 is a polymer layer, which may also be formed of a photo-sensitive dielectric material such as benzocyclobutene (BCB), polyimides, polybenzoxazole (PBO), or the like. In accordance with alternative embodiments, dielectric layer 52 is formed of or comprises a non-photo-sensitive polymer, an inorganic dielectric material (such as silicon oxide), or the like.

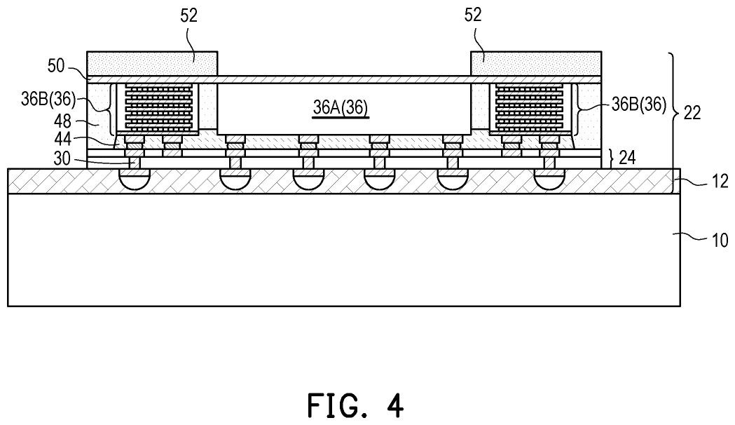

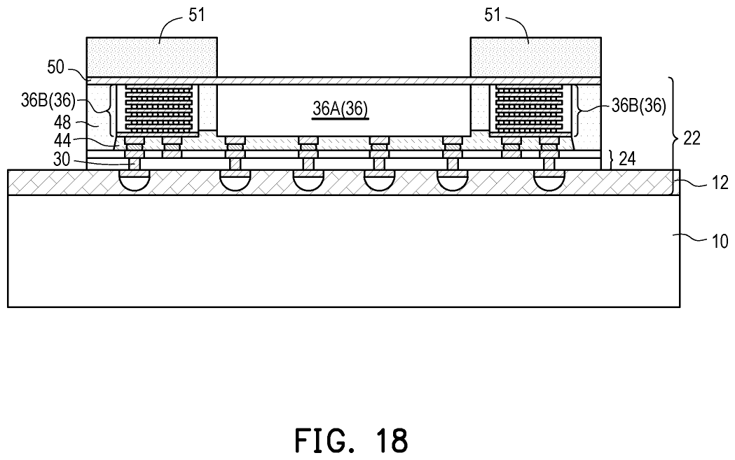

Referring to FIG. 4, dielectric layer 52 is patterned, so that the portions of dielectric layer 52 overlapping package components 36A (which may dissipate more heat than package components 36B) are removed. In accordance with some embodiments in which dielectric layer 52 comprises a photo-sensitive material, the patterning includes placing a photolithography mask (not shown) over dielectric layer 52, performing a light-exposure process to expose dielectric layer 52, and developing the dielectric layer 52. In accordance with alternative embodiments, dielectric layer 52 is patterned through an etching process, during which a patterned photoresist (not shown) is formed over dielectric layer 52 to define the portions of dielectric layer 52 to be etched. The corresponding processes are discussed in detail referring to FIGS. 18-22.

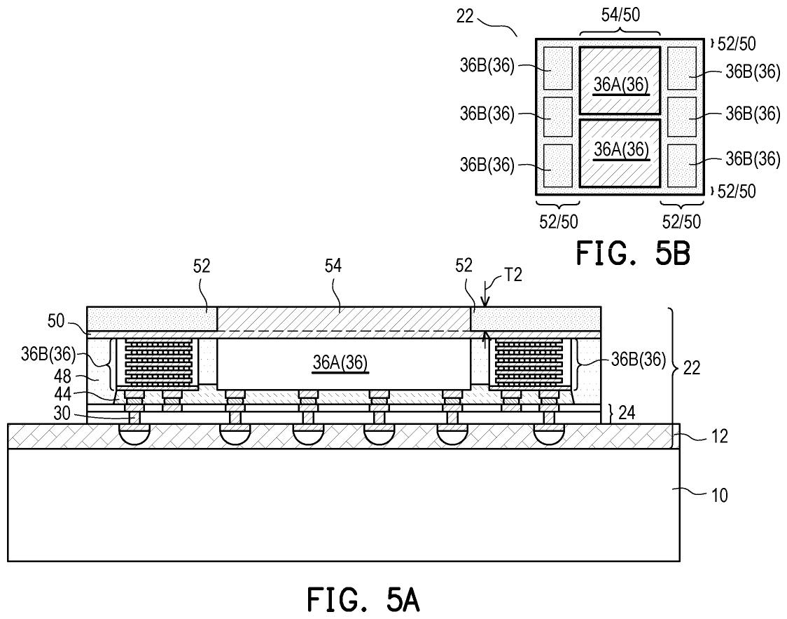

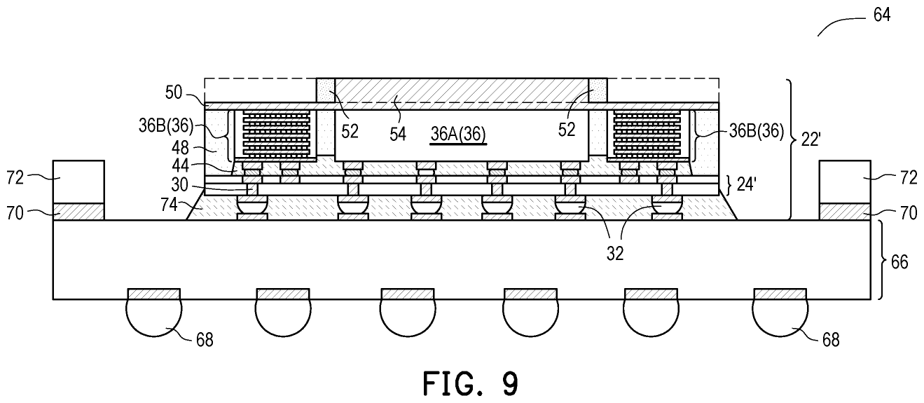

FIG. 5A illustrates the formation of metal TIM 54, which is a metal plate. In accordance with some embodiments, metal TIM 54 is formed through a plating process, which is performed using metal layer 50 as a metal seed layer. Metal TIM 54 may include any suitable metal that has a high melting point and a high thermal conductivity. For example, the melting point of metal TIM 54 may be higher than the melting point of solder such as the solder regions 32 and 68 as shown in FIG. 9. The thermal conductivity of metal TIM 54 may be higher than about 100 W/m·K (Watts per meter Kelvin), higher than about 200 W/m·K, or higher. For example, metal TIM 54 may be formed of or comprise copper, which has a thermal conductivity equal to about 401 W/m·K.

Metal TIM 54 and the underlying portion of metal layer 50 collectively form a metal feature, and may or may not have a distinguishable interface in between. Metal TIM 54 and the metal layer 50 also collectively form an upper portion and a lower portion, respectively, of the metal feature.

In accordance with some embodiments, after the plating, a planarization process is performed to level the top surface of TIM 54 with the top surface of dielectric layer 52. In the resulting structure, the thickness T2 of metal TIM 54 may be in the range between about 20 μm and about 50 μm.

FIG. 5B illustrates a top view of the structure as shown in FIG. 5A. In accordance with some embodiments, metal TIM 54 covers the package components 36A, and dielectric layer 52 covers package components 36B and the overlying portion of metal layer 50.

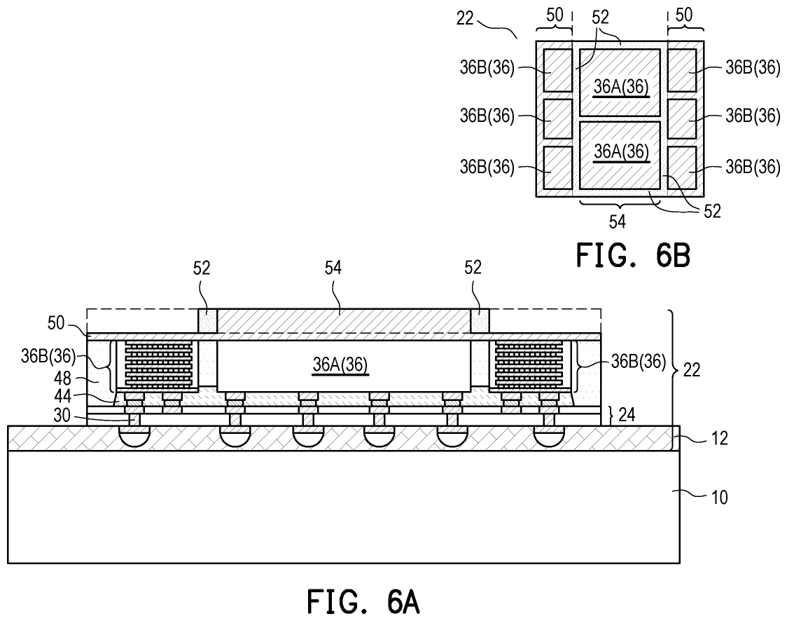

FIG. 6A illustrates the patterning of dielectric layer 52 in accordance with some embodiments. In accordance with some embodiments, dielectric layer 52 is patterned through an etching process, during which a patterned photoresist is formed over dielectric layer 52 to define the portions of dielectric layer 52 to be etched. After the etching process, the remaining portions of dielectric layer 52 have their edges in contact with the edges of metal TIM 54, while some portions of the dielectric layer 52 over package components 36B are removed. The underlying portions of metal layer 50 are thus exposed.

In accordance with alternative embodiments, instead of patterning dielectric layer 52, with some portions of dielectric layer 52 remaining, dielectric layer 52 may be fully removed. Dielectric layer 52 thus defines where metal TIM 54 is formed. In accordance with yet alternative embodiments, dielectric layer 52 is not patterned, and remains as a blanket layer over package component 22. Accordingly, dashed frames are illustrated to present the portion of the dielectric layer 52 that may remain, or may be removed.

FIG. 6B illustrates a top view of the structure as shown in FIG. 6A. In accordance with some embodiments, metal TIM 54 covers the package components 36A, and the remaining portions of dielectric layer 52 includes portions on opposing sides of metal TIM 54. The remaining portions of dielectric layer 52 may also form a ring encircling metal TIM 54.

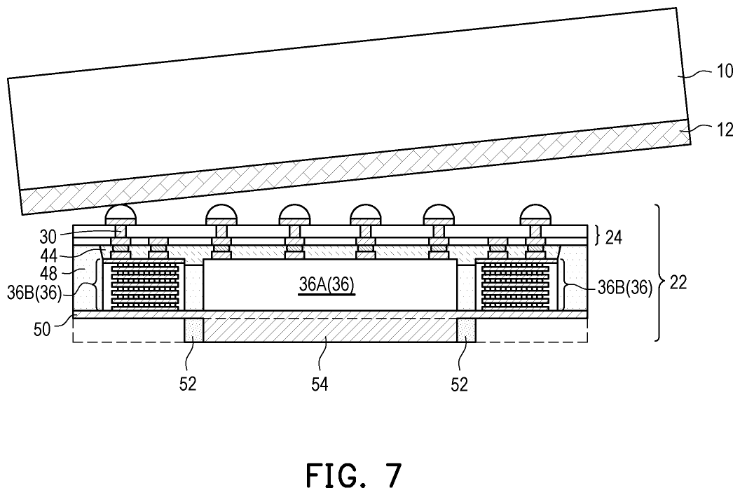

Next, Referring to FIG. 7, package component 22, which includes the metal TIM 54, is de-bonded from carrier 10. In accordance with some embodiments, a light beam such as a laser beam is projected on release film 12, and release film 12 is de-composed under the heat of the light beam. Package component 22 and the overlying structures are thus released from carrier 10.

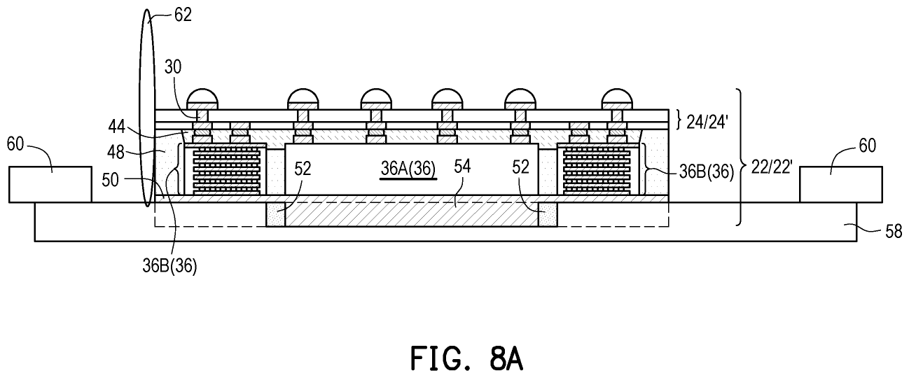

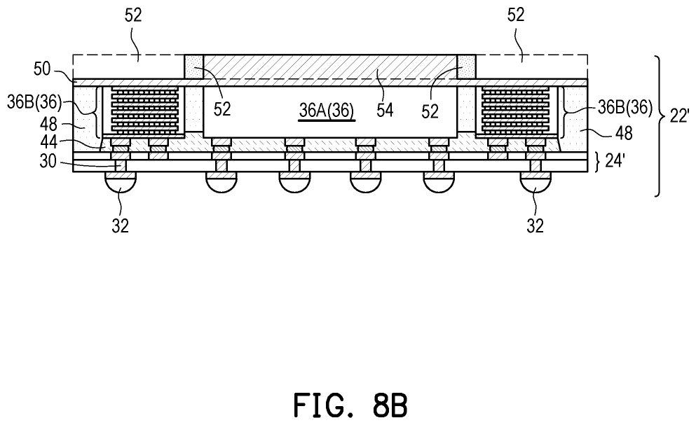

In a subsequent process, as shown in FIG. 8A, package component 22 is placed on dicing tape 58, which is fixed on frame 60. A singulation process may be performed to saw package component 22, so that package component 22 (which may be a reconstructed wafer) is separated into discrete and identical packages 22′ (also referred to as package components 22′). The dies 24′ in wafer 24 are also separated, and may be interposers. Packages 22′ are alternatively referred to as TIM-built-in packages hereinafter, and metal TIM 54 is referred to as built-in metal TIM 54. The sawing process may be performed using, for example, blade 62.

A resulting TIM-built-in package 22′ is also illustrated in FIG. 8B. TIM-built-in package 22′ includes a metal layer 50. Due to the singulation process in which metal layer 50 is sawed, the edges of metal layer 50 are vertically aligned to the respective edges of the underlying molding compound 48, and are vertical aligned to the edges of interposers 24′. In accordance with some embodiments in which dielectric layer 52 is not patterned, as indicated by the dashed frames, the edges of metal layer 50 are vertically aligned to the respective edges of dielectric layer 52.

FIGS. 9, 13, 16, and 17 illustrate some packages 64 formed based on the TIM-built-in package 22′ as shown in FIG. 8B in accordance with various embodiments. Referring to FIG. 9, TIM-built-in package 22′ is bonded to package component 66. Underfill 74 is also dispensed into the gap between package component 66 and TIM-built-in package 22′. In accordance with some embodiments, TIM-built-in package 22′ is bonded to package component 66 through electrical connectors 32 (alternatively referred to as solder regions 32 when being solder regions), which may be reflowed. Metal TIM 54 has a high melting point, which may be about 1,084° C. when metal TIM 54 is formed of copper. Solder regions 32, on the other hand, have a low melting point, which may be around 200° C. and about 220° C. The reflow may be performed at a temperature in the range between about 230° C. and about 250° C. Accordingly, metal TIM 54 is not molten.

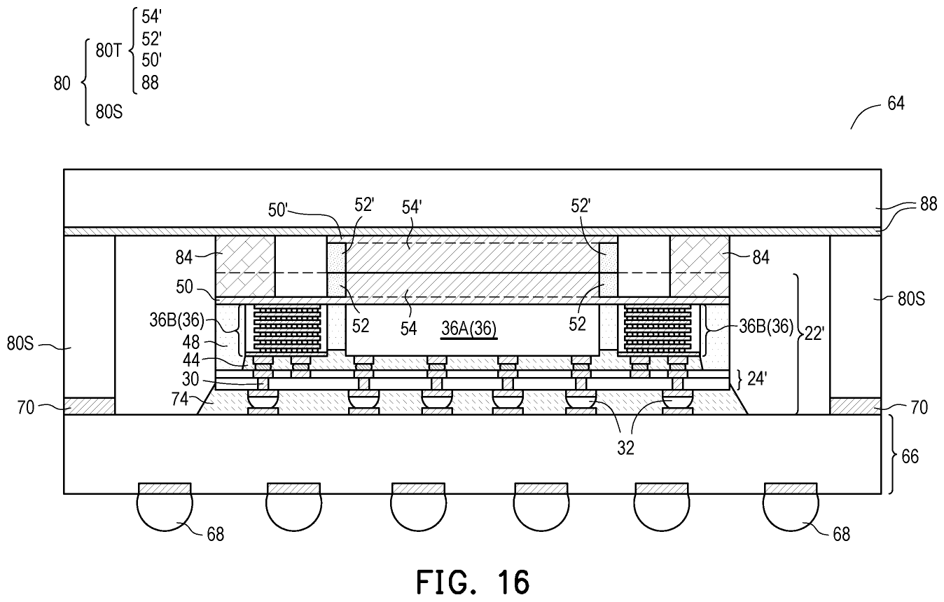

Package component 66 may further include electrical connectors 68, which may be solder regions. Electrical connectors 68 are electrically connected to electrical connectors 32 through the electrical conductive paths (not shown) inside package component 66. Brace ring 72 (a fastener ring) may be attached to package component 66 through adhesive 70, so that brace ring 72 may provide mechanical support to package component 66 and reduces warpage. In package 64, metal TIM 54 may be used as a heat sink in accordance with some embodiments. Alternatively, another metal lid (which is used as heat sink) may be attached to metal TIM 54. The resulting structure is similar to the structure shown in FIG. 16, except that the brace ring 72 in FIG. 9 may replace the skirt portion 80S of the metal lid 80 in FIG. 16.

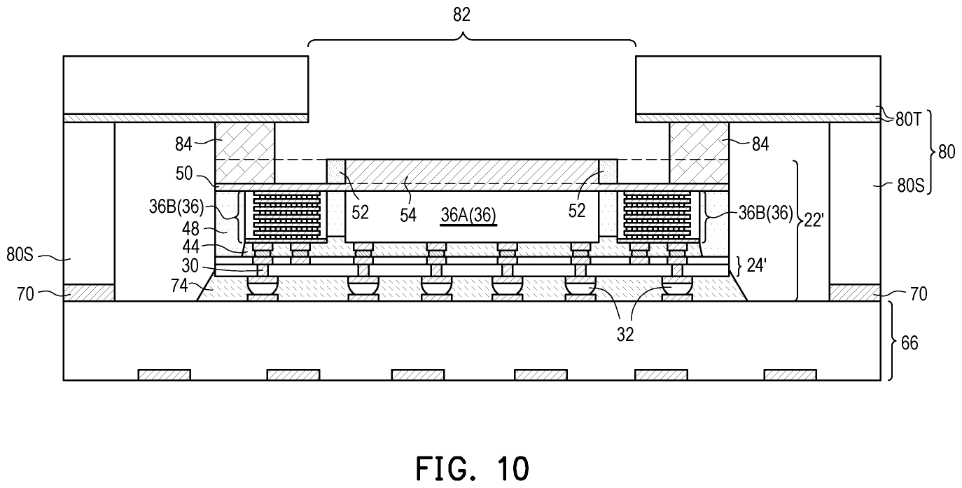

FIGS. 10 through 13 illustrate the formation of the package 64 incorporating the built-in metal TIM 54 in accordance some embodiments. Referring to FIG. 10, sunroof metal lid 80 is attached to package component 66 through adhesive 70. In accordance with some embodiments, sunroof metal lid 80 includes skirt portion 80S and top portion 80T joined with the skirt portion 80S. The skirt portion 80S may form a full ring when viewed from the top of the structure. The top portion 80T may also form a full ring encircling opening 82, which is directly over metal TIM 54. Dielectric layer 52 may also be directly underlying opening 82 in accordance with some embodiments. Alternatively, dielectric layer 52 may be overlapped by the top portion 80T.

In accordance with some embodiments, buffer material 84 is dispensed between the top portion 80T and metal layer 50. Alternatively, when dielectric layer 52 is not patterned and extends to the edge of encapsulant 48, buffer material 84 may be dispensed on dielectric layer 52. Buffer material 84 may be formed of an adhesive in accordance with some embodiments. Alternatively, buffer material 84 may be formed of or comprises a solid TIM, a flowable TIM (including a polymer and thermally conductive particles therein), or the like. The flowable TIM has a thermal conductivity value higher than 1 W/m·K, 4 W/m·K, 10 W/m·K, or higher. Buffer material 84, when being the flowable TIM, is dispensed and cured.

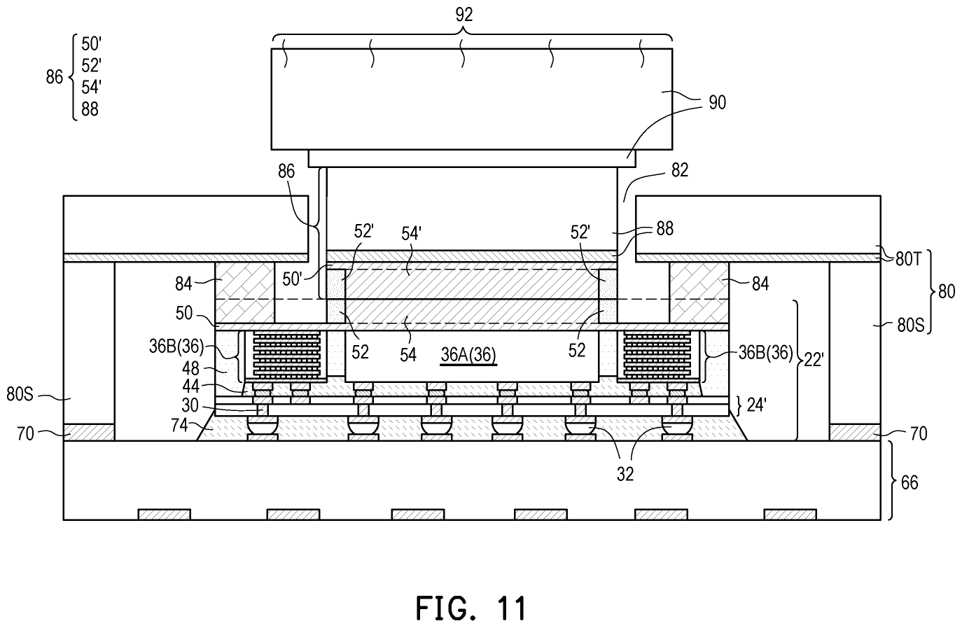

Referring to FIG. 11, metal lid 86 is placed over metal TIM 54. In accordance with some embodiments, metal lid 86 includes metal body 88, which may be formed of or comprise copper, aluminum, or the like. Metal lid 86 further includes metal layer 50′, dielectric layer 52′, and metal TIM 54′, which are formed on metal body 88. In accordance with some embodiments, the materials, the structures, and the formation methods of metal layer 50′, dielectric layer 52′, and metal TIM 54′ may be essentially the same as that of metal layer 50, dielectric layer 52, and metal TIM 54, respectively, as discussed referring to FIGS. 2-4, 5A, and 6A. For example, the formation process may include depositing metal layer 52′ on metal body 88, forming and patterning dielectric layer 52′, plating metal TIM 54′, planarizing dielectric layer 52′ and metal TIM 54′, and patterning dielectric layer 52′. The rest of the details may be found referring to the discussion of FIGS. 2-4, 5A, and 6A, and are not repeated herein.

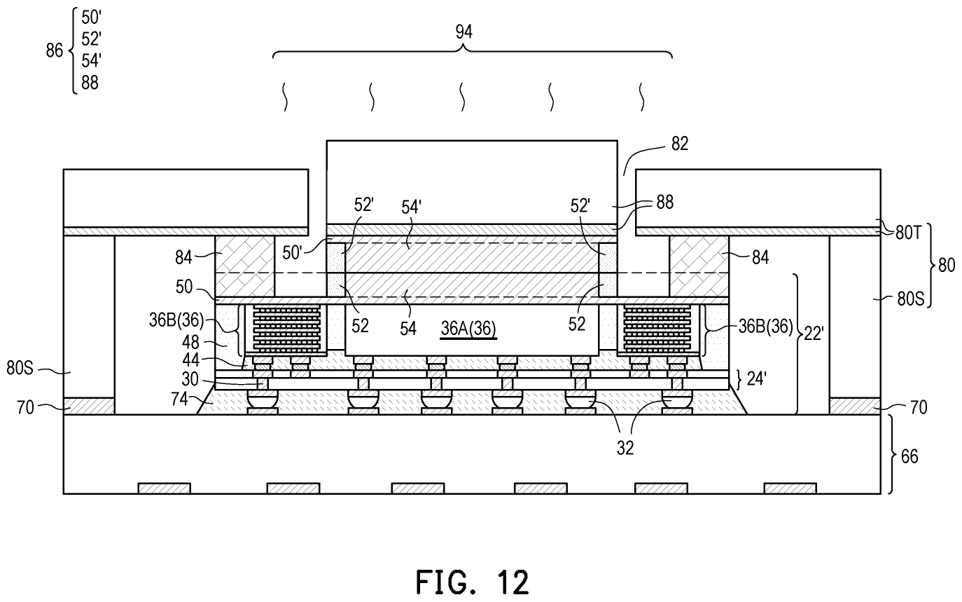

In accordance with some embodiments, metal TIM 54′ is vertically aligned to, and is in physical contact with metal TIM 54. Dielectric layer 52′ is vertically aligned to, and is in physical contact with dielectric layer 52. A thermal compression process 92 is then performed, for example, using compression head 90 to push metal lid 86 against metal TIM 54 and dielectric layer 52. The compression head 90 is heated. Accordingly, during the thermal compression process 92, metal lid 54, dielectric layer 52, metal lid 54′, and dielectric layer 52′ are heated, for example, to temperatures in the range between about 250° C. and about 350° C. After the thermal compression process 92, anneal process 94 is performed, as shown in FIG. 12.

As a result of the thermal compression process 92 and anneal process 94, the metals in metal TIM 54 and metal TIM 54′ are bonded through metal-to-metal direct bonding due to the inter-diffusion of the metals. Dielectric layer 52 and dielectric layer 52′ may also be bonded to each other. For example, when dielectric layer 52 and dielectric layer 52′ are inorganic dielectric materials, the bonding may be through fusion bonding. When dielectric layer 52 and dielectric layer 52′ are polymers, the chains of the polymer in dielectric layer 52 may be joined with the chains in dielectric layer 52′ to form longer chains that extend into both of dielectric layer 52 and dielectric layer 52′. Alternatively, dielectric layer 52 is in contact with, but is not bonded to, dielectric layer 52′. Accordingly, dielectric layers 52 and 52′ are separable at where they contact.

The interfaces between TIM 54 and metal TIM 54′ may be, or may not be, distinguishable. TIM 54 and metal TIM 54′ may be slightly offset with each other, so that their joining position may be determined. For example, TIM 54 may be shifted slightly left, so that TIM 54 extends laterally beyond the left edge of TIM 54′, and TIM 54′ extends laterally beyond the right edge of TIM 54. Dielectric layer 52 may also shift slightly left relative to dielectric layer 52′.

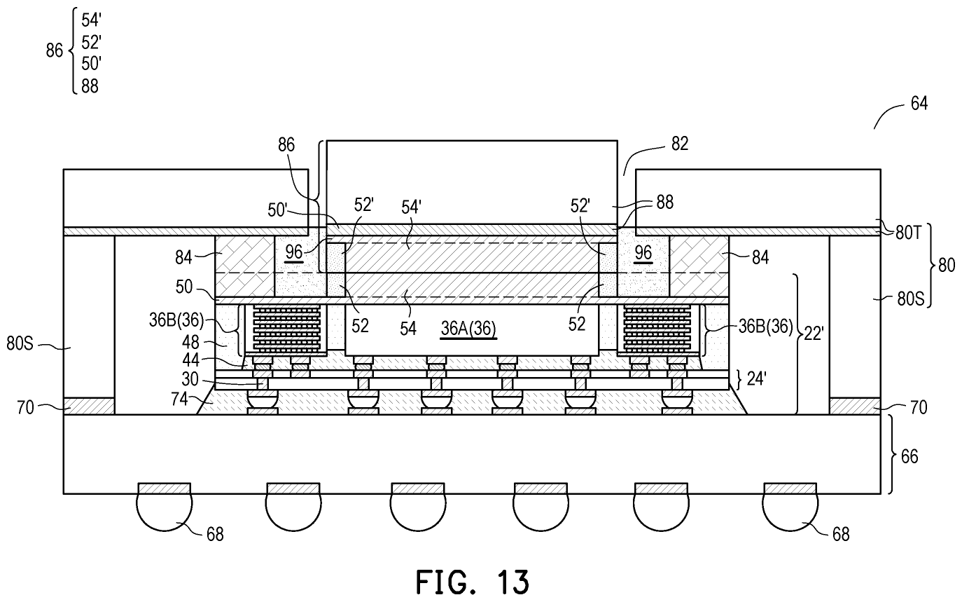

Referring to FIG. 13, electrical connectors 68 are formed on package component 66 to finish the formation of package 64. In accordance with some embodiments, the formation of electrical connectors 68 include placing solder balls on package component 66, and reflowing the solder balls to form solder regions.

In accordance with some embodiments, a thermally conductive material 96 may be dispensed into the gap between sunroof metal lid 80 and metal lid 86. The thermally conductive material 96 may also be dispensed into the remaining gaps under the sunroof metal lid 80 and metal lid 86. The thermally conductive material 96 is cured into a solid after being dispensed. The thermal conductivity of the thermally conductive material 96 may be higher than 1 W/m·K, 4 W/m·K, 10 W/m·K, or higher. The thermally conductive material 96 may be a thermal grease, a thermal gel, a phase change material, a thermally conductive adhesive, a metal with a low melting point such as In, Sn, Ga, or the like, a material including graphite film and an adhesive therein, or the like.

When the materials with the low melting points are used, the thermally conductive material 96 may be dispensed after the formation of electrical connectors 68 to avoid being re-molten during the reflow of electrical connectors 68. Otherwise, the thermally conductive material 96 may be dispensed before or after the formation of electrical connectors 68.

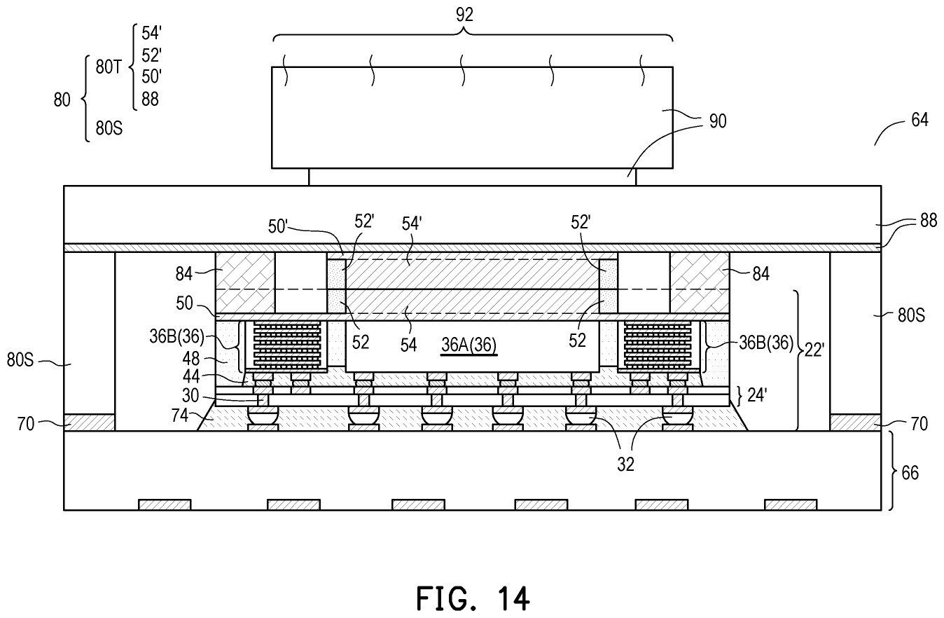

FIGS. 14 through 16 illustrate the formation of package 64 including a metal lid having a blanket top portion in accordance with some embodiments. Unless specified otherwise, the materials, the structures, and the formation processes of the components in these embodiments are essentially the same as the like components denoted by like reference numerals in the preceding embodiments. The details regarding the materials, the structures, and the formation processes provided in each of the embodiments throughout the description may be applied to any other embodiment whenever applicable.

Referring to FIG. 14, package 22′ is bonded to package component 66. Underfill 74 is dispensed between package 22′ and package component 66. Metal lid 80 is attached to package component 66 through adhesive 70, with buffer material 84 being dispensed between the top portion 80T and metal layer 50. Buffer material 84 may also be formed of an adhesive, a TIM, or the like. Buffer material 84 may also be formed of a thermal grease, a thermal gel, a phase change material, a thermally conductive adhesive, a metal with a low melting point such as In, Sn, Ga, or the like, a material including graphite film and an adhesive therein, or the like.

Metal lid 80 may include skirt portion 80S, and top portion 80T joined to skirt portion 80S. Top portion 80T may include metal body 88, metal layer 50′, dielectric layer 52′, and metal TIM 54′. The formation of the top portion 80T may be essentially the same as the formation of metal lid 86 as shown in FIG. 11. For example, the formation process of the top portion 80T may include depositing metal layer 52′ on metal body 88, forming and patterning dielectric layer 52′, plating metal TIM 54, planarizing dielectric layer 52′ and plating metal TIM 54, and patterning dielectric layer 52′. The top portion 80T may be formed at wafer level, with the metal body 88 being a part of a metal wafer.

After the formation of the dielectric layer 52′ and the metal TIMs 54′, metal layer 50′ may be patterned to remove the unwanted portions. Alternatively, metal layer 50′ may be left without being patterned. The wafer-level top portion 80T may then be sawed to form a plurality of portions, each including a portion as shown in FIG. 14.

The skirt portions 80S may then be bonded to the top portions 80T to form metal lids 80. In accordance with the embodiments in which the metal layer 50′ is left without being patterned, the metal layer 50′ will overlap and join the skirt portion 80S to form a horizontal interface.

Further referring to FIG. 14, a thermal compression process 92 is performed, for example, using compression head 90 to push metal lid 80 against metal TIM 54 and dielectric layer 52. The compression head 90 is heated. Accordingly, during the thermal compression process 92, metal lid 54, dielectric layer 52, metal lid 54′, and dielectric layer 52′ are also heated. The temperature and the duration of the thermal compression process 92 may be essentially the same as discussed referring to preceding embodiments.

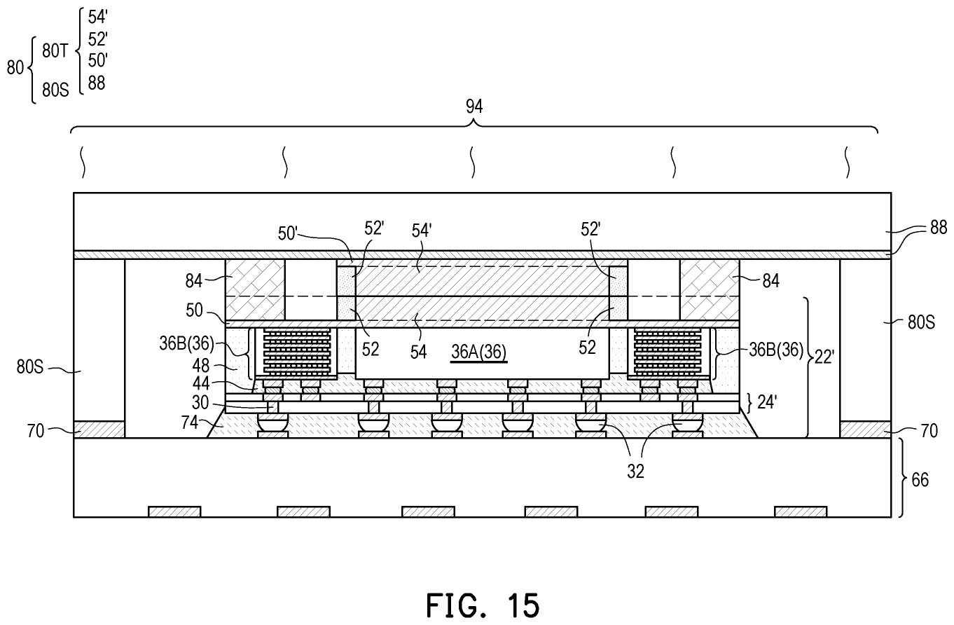

After the thermal compression process 92, anneal process 94 is performed, as shown in FIG. 15. The temperature and the duration of the anneal process 94 may be essentially the same as discussed referring to preceding embodiments. As a result of the thermal compression process 92 and anneal process 94, the metals in metal TIM 54 and metal TIM 54′ are bonded through metal-to-metal direct bonding due to the inter-diffusion of the metals. Dielectric layer 52 and dielectric layer 52′ may also be bonded to each other, or may be in contact with, but not bonded to, each other.

Referring to FIG. 16, electrical connectors 68 are formed on package component 66 to finish the formation of package 64. In accordance with some embodiments, the formation of electrical connectors 68 include placing solder balls on package component 66, and reflowing the solder balls to form solder regions. Package 64 is thus formed.

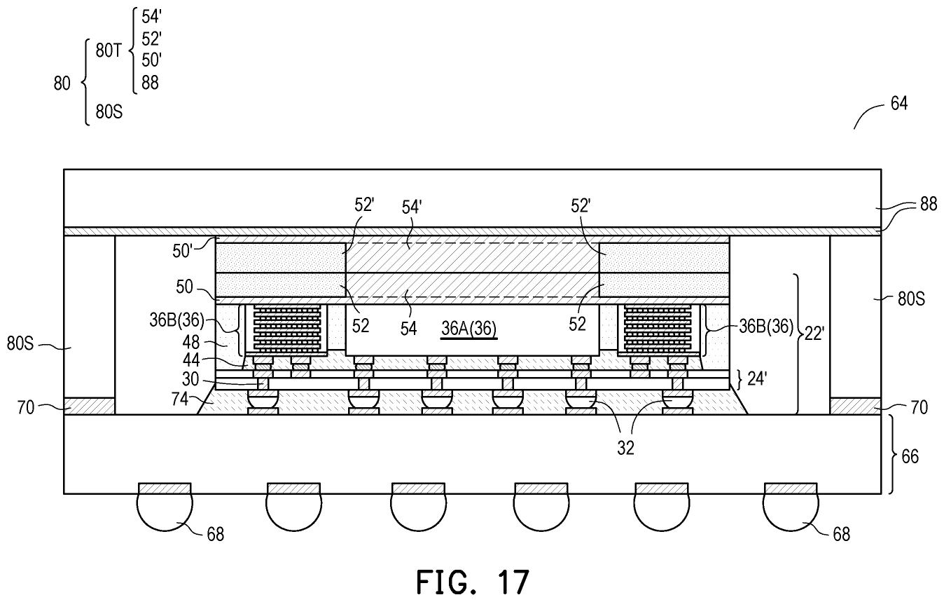

FIG. 17 illustrates package 64 formed in accordance with alternative embodiments. These embodiments are essentially the same as the package 64 in FIG. 16, except that dielectric layer 52 is not patterned. Alternatively stated, after the process as shown in FIG. 5A, the process shown in FIG. 6A is not performed. Dielectric layer 52′ may also be un-patterned. The lateral size of dielectric layer 52′ may also match the size of dielectric layer 52. Dielectric layers 52 and 52′ may extend to positions aligning the edges of encapsulant 48.

FIGS. 18 through 22 illustrate the formation of package 22′ in accordance with alternative embodiments. These embodiments are similar to the embodiments as shown in FIGS. 4, 5A, 5B, 6A, and 6B, except that instead of using the same dielectric layer 52 as being the plating mask and the dielectric layer in the final structure, a photoresist is formed as the plating mask, and is then removed, followed by the formation of the dielectric layer 52.

Referring to FIG. 18, package component 22 is formed on carrier 10. The details of the package component 22 are essentially the same as discussed referring to FIGS. 1 and 2. Next, as also shown in FIG. 18, metal layer 50 is deposited as a top portion of package component 22. Plating mask 51 is then formed over metal layer 50 and then patterned. The opening in plating mask 51 may overlap package components 36A, which generate more heat than package components 36B during their operation. Plating mask 51 may be formed of a photoresist in accordance with some embodiments.

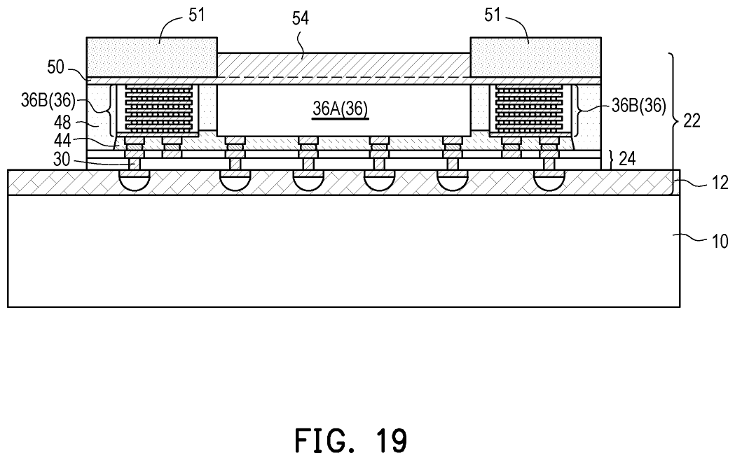

Next, as shown in FIG. 19, a plating process is performed to form metal TIM 54. During the plating, metal layer 50 may act as a metal seed layer. The metal TIM 54 is plated to a thickness greater than that in the final package. Plating mask 51 is then removed, for example, in an ashing process, an etching process, or the like.

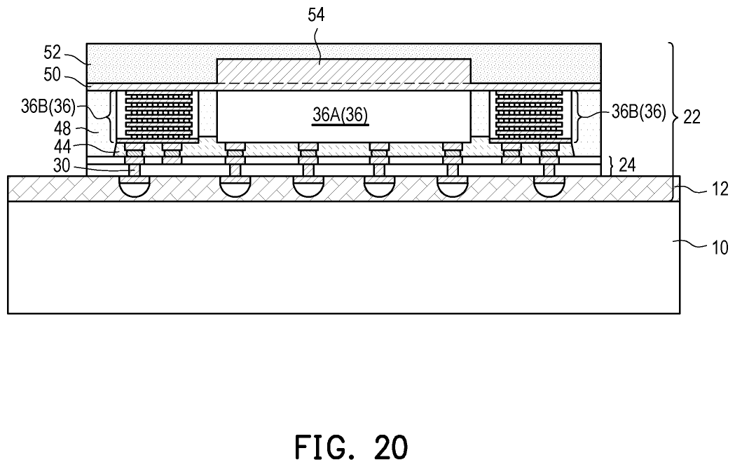

Referring to FIG. 20, dielectric layer 52 is formed. The formation process may include spin-on coating, Atomic Layer Deposition (ALD), Chemical Vapor Deposition (CVD), or the like, depending on the material of dielectric layer 52. For example, when dielectric layer 52 comprises polyimide, BCB, PBO, or the like, the formation process may include spin-on coating and curing. When dielectric layer 52 comprises an inorganic dielectric material such as silicon oxide, the formation process may include ALD, CVD, or the like.

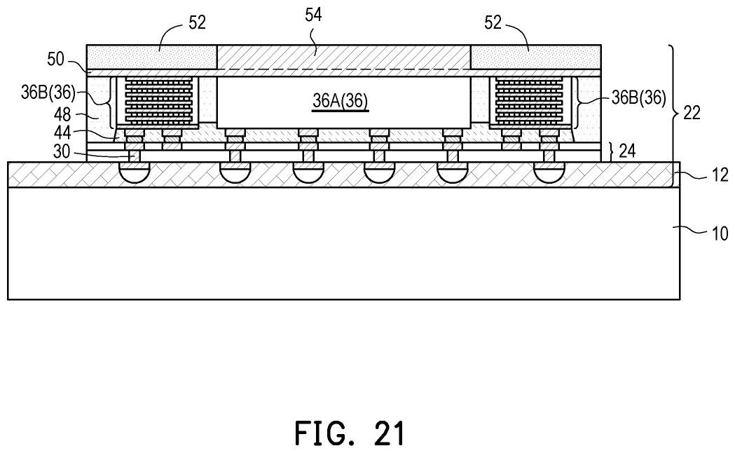

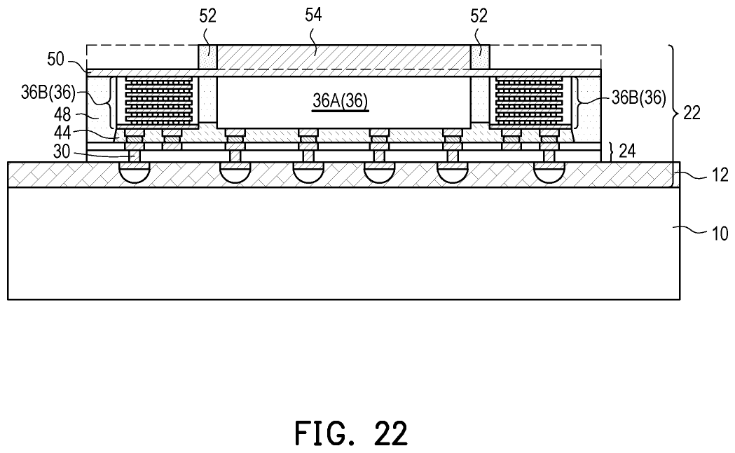

FIG. 21 illustrates a planarization process to planarize the top surfaces of metal TIM 54 and dielectric layer 52. The planarization process may be performed through a CMP process or a mechanical grinding process. FIG. 22 illustrates a patterning process to pattern dielectric layer 52 in accordance with some embodiments. In accordance with alternative embodiments, dielectric layer 52 is not patterned. Accordingly, dashed frames are illustrated to represent the portions of the dielectric layer 52 that may remain or may be removed.

In above-illustrated embodiments, some processes and features are discussed in accordance with some embodiments of the present disclosure to form a three-dimensional (3D) package. Other features and processes may also be included. For example, testing structures may be included to aid in the verification testing of the 3D packaging or 3DIC devices. The testing structures may include, for example, test pads formed in a redistribution layer or on a substrate that allows the testing of the 3D packaging or 3DIC, the use of probes and/or probe cards, and the like. The verification testing may be performed on intermediate structures as well as the final structure. Additionally, the structures and methods disclosed herein may be used in conjunction with testing methodologies that incorporate intermediate verification of known good dies to increase the yield and decrease costs.

The embodiments of the present disclosure have some advantageous features. By using a metal (such as copper) that has a high melting point to form a metal TIM, the metal TIM is not reflowed in subsequent reflow processes, and no void will be generated in the metal TIM to degrade its heat-conducting ability. The metal TIM also has a higher thermal conductivity than conventional TIMs that include polymer/epoxy/resin and thermally conductive particles. The formation of the dielectric layer on the metal TIM also improves the bonding of the corresponding structure with the metal lid, and may also be used to define the locations and the sizes of the metal TIM.

In accordance with some embodiments of the present disclosure, a method comprises depositing a first metal layer on a package component, wherein the package component comprises a first device die; forming a first dielectric layer on the package component; plating a metal thermal interface material on the first metal layer, wherein the first dielectric layer comprises portions on opposing sides of the metal thermal interface material; and bonding a heat sink on the metal thermal interface material, wherein the heat sink comprises a second metal layer physically joined to the metal thermal interface material.

In an embodiment, the heat sink further comprises a second dielectric layer on opposing sides of the second metal layer, and wherein the second dielectric layer is further in contact with the first dielectric layer. In an embodiment, the method further comprises, after the metal thermal interface material is plated, patterning the first dielectric layer to reveal a portion of the first metal layer. In an embodiment, the package component further comprises a second device die, wherein the first device die is configured to generate more heat than the second device die, and wherein the metal thermal interface material overlaps the first device die, and a portion of the first dielectric layer overlapping the second device die is removed by the patterning the first dielectric layer.

In an embodiment, the method further comprises performing a planarization process to level top surfaces of the first dielectric layer and the metal thermal interface material. In an embodiment, the forming the first dielectric layer comprises dispensing a polymer. In an embodiment, the dispensing the polymer comprises dispensing BCB. In an embodiment, the heat sink comprises a top metal lid, and the method further comprises attaching a sunroof metal lid through an adhesive, wherein the adhesive comprises a bottom surface contacting the first metal layer, and a top surface contacting an additional bottom surface of the sunroof metal lid.

In an embodiment, the method further comprises forming a patterned plating mask over the first metal layer, wherein the metal thermal interface material is plated using the patterned plating mask to define patterns; removing the patterned plating mask; forming a blanket dielectric layer to cover both of the metal thermal interface material and the first metal layer; and performing a planarization process on the blanket dielectric layer to reveal the metal thermal interface material, wherein remaining portions of the blanket dielectric layer comprise the first dielectric layer. In an embodiment, the bonding the heat sink on the metal thermal interface material comprises a compression bonding process; and an anneal process performed after the compression bonding process. In an embodiment, the metal thermal interface material comprises copper.

In accordance with some embodiments of the present disclosure, a structure comprises a package component comprising a first device die; a metal layer over and in physical contact with the package component; a metal thermal interface material on the metal layer; and a heat sink bonding to the metal thermal interface material, wherein the heat sink comprises a meta layer physically joined to the metal thermal interface material. In an embodiment, the metal layer extends laterally beyond edges of the metal thermal interface material.

In an embodiment, the structure further comprises a first dielectric layer over and contacting the metal layer, wherein a first sidewall of the first dielectric layer contacts a second sidewall of the metal thermal interface material to form an interface. In an embodiment, the metal layer further extends laterally beyond additional edges of the first dielectric layer. In an embodiment, the first dielectric layer comprises a polymer. In an embodiment, the heat sink further comprises a second dielectric layer bonding to the first dielectric layer.

In accordance with some embodiments of the present disclosure, a structure comprises an interposer comprising first edges; a first device die and a second device die over and bonding to the interposer; a metallic feature over and contacting the first device die and the second device die, wherein the metallic feature comprises a lower portion comprising second edges vertically aligned to respective ones of the first edges; and an upper portion, wherein the upper portion is laterally recessed from the upper portion; and a metal lid over and bonding to the upper portion. In an embodiment, the upper portion comprises copper, and the upper portion is physically joined to an additional copper feature in the metal lid.

In an embodiment, the structure further comprises a first dielectric layer over and contacting the lower portion, with the first dielectric layer and the upper portion forming a first vertical interface in between; and a second dielectric layer over and bonding to the first dielectric layer, with the second dielectric layer and an additional portion of the metal lid forming a second vertical interface in between.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method comprising:
depositing a first metal layer on a package component, wherein the package component comprises a first device die;
forming a first dielectric layer on the package component;
forming a metal thermal interface material on the first metal layer, wherein the first dielectric layer comprises portions on opposing sides of the metal thermal interface material; and
bonding a heat sink on the metal thermal interface material, wherein the heat sink comprises a second metal layer bonding to the metal thermal interface material through metal-to-metal direct bonding.

2. The method of claim 1, wherein the heat sink further comprises a second dielectric layer on opposing sides of the second metal layer, and wherein the second dielectric layer is further in contact with the first dielectric layer.

3. The method of claim 1 further comprising, after the metal thermal interface material is plated, patterning the first dielectric layer to reveal a portion of the first metal layer.

4. The method of claim 3, wherein the package component further comprises a second device die, wherein the first device die is configured to generate more heat than the second device die, and wherein the metal thermal interface material overlaps the first device die, and a portion of the first dielectric layer overlapping the second device die is removed by the patterning the first dielectric layer.

5. The method of claim 1 further comprising performing a planarization process to level top surfaces of the first dielectric layer and the metal thermal interface material.

6. The method of claim 1, wherein the forming the first dielectric layer comprises dispensing a polymer.

7. The method of claim 6, wherein the dispensing the polymer comprises dispensing benzocyclobutene (BCB).

8. The method of claim 1, wherein the heat sink comprises a top metal lid, and the method further comprises attaching a sunroof metal lid through an adhesive, wherein the adhesive comprises a bottom surface contacting the first metal layer, and a top surface contacting an additional bottom surface of the sunroof metal lid.

9. The method of claim 1 further comprising:
forming a patterned plating mask over the first metal layer, wherein the metal thermal interface material is plated using the patterned plating mask to define patterns;
removing the patterned plating mask;
forming a blanket dielectric layer to cover both of the metal thermal interface material and the first metal layer; and
performing a planarization process on the blanket dielectric layer to reveal the metal thermal interface material, wherein remaining portions of the blanket dielectric layer comprise the first dielectric layer.

10. The method of claim 1, wherein the bonding the heat sink on the metal thermal interface material comprises:
a compression bonding process; and
an anneal process performed after the compression bonding process.

11. The method of claim 1, wherein the metal thermal interface material comprises copper.

12. A structure comprising:
a package component comprising a first device die;
a metal layer over and in physical contact with the package component;
a metal thermal interface material on the metal layer; and
a heat sink bonding to the metal thermal interface material, wherein the heat sink comprises a meta layer physically joined to the metal thermal interface material.

13. The structure of claim 12, wherein the metal layer extends laterally beyond edges of the metal thermal interface material.

14. The structure of claim 12 further comprising a first dielectric layer over and contacting the metal layer, wherein a first sidewall of the first dielectric layer contacts a second sidewall of the metal thermal interface material to form an interface.

15. The structure of claim 14, wherein the metal layer further extends laterally beyond additional edges of the first dielectric layer.

16. The structure of claim 14, wherein the first dielectric layer comprises a polymer.

17. The structure of claim 14, wherein the heat sink further comprises a second dielectric layer bonding to the first dielectric layer.

18. A structure comprising:
an interposer comprising first edges;
a first device die and a second device die over and bonding to the interposer;
a metallic feature over and contacting the first device die and the second device die, wherein the metallic feature comprises:
a lower portion comprising second edges vertically aligned to respective ones of the first edges; and
an upper portion, wherein the upper portion is laterally recessed from the upper portion; and
a metal lid over and bonding to the upper portion.

19. The structure of claim 18, wherein the upper portion comprises copper, and the upper portion is physically joined to an additional copper feature in the metal lid.

20. The structure of claim 18 further comprising:
a first dielectric layer over and contacting the lower portion, with the first dielectric layer and the upper portion forming a first vertical interface in between; and
a second dielectric layer over and bonding to the first dielectric layer, with the second dielectric layer and an additional portion of the metal lid forming a second vertical interface in between.
